(19) United States
(12) Patent Application Publication
(10) Pub. No.: US 2010/0214749 A1
(43) Pub. Date: Aug. 26, 2010

(54) Circuit Board Retainer with Insertion and Extraction Lever

(76) Inventor: Chang Sob Lee, Moorpark, CA (US)

Correspondence Address: CTS Corporation, 2375 Cabot Drive, Lisle, IL, 60532, US

(21) Appl. No.: 12/566,469

(22) Filed: Sep. 24, 2009

Related U.S. Application Data
(60) Provisional application No. 61/194,186, filed on Sep. 25, 2008.
(60) Provisional application No. 61/197,857, filed on Oct. 30, 2008.

(51) Int. Cl. H05K 5/02

(52) U.S. Cl. 361/754

(57) ABSTRACT

A lever assembly for a retainer which retains a circuit board in an enclosure. The retainer includes a rotatable camshaft. The lever assembly includes a bracket on the enclosure and a rotatable lever at the end of the camshaft. The lever includes a distal arm which engages with the bracket to insert and extract the circuit board into and from the enclosure. A spring element, coupled to either the lever or the end of the camshaft, creates a spring resistance force which biases the lever against the camshaft. In one embodiment, the spring element is a clip on the camshaft which exerts a compressive spring force against the lever. In another embodiment, a spring pin is coupled to the lever and exerts a compressive spring force against the camshaft.

### CROSS-REFERENCE TO RELATED APPLICATIONS

This application claims the benefit of the filing date and disclosure of U.S. Provisional Application Ser. No. 61/194,186 filed on Sep. 25, 2008 and U.S. Provisional Patent Application Ser. No. 61/197,857 filed on Oct. 30, 2008, both of which are explicitly incorporated herein by reference as are all references cited therein.

### FIELD OF THE INVENTION

The present invention generally relates to a circuit board retainer adapted to hold a printed circuit board in an enclosure or housing and, in particular, to a lever assembly associated with the retainer for inserting, locking, and extracting the circuit board to and from the enclosure.

### DESCRIPTION OF THE RELATED ART

Printed circuit boards for various electronic devices are commonly grouped together and mounted in housings or enclosures. The enclosure may be referred to as a rack and may contain a backplane with attached backplane connectors.

Various types of structures are available for releasably retaining and locking the printed circuit boards in these enclosures. One of these retainer structures is disclosed in, for example, U.S. Pat. No. 5,200,882.

The present invention is directed to a retainer of the type disclosed in U.S. Pat. No. 5,200,882 which does not require the use of any tools to insert, lock, or extract the board to and from the housing or enclosure.

### SUMMARY OF THE INVENTION

The present invention is directed to a lever assembly for use with a retainer adapted to releasably retain a circuit board in an enclosure. The lever assembly comprises a rotatable lever which includes a handle and a distal arm extending outwardly from a distal end of the handle and a bracket which is coupled to the enclosure and adapted to engage with the arm of the lever in response to movement of the lever to facilitate the insertion and extraction of the circuit board into and from the enclosure.

In one embodiment, the bracket includes a base which is coupled to the enclosure and a finger which is spaced from the base so as to define a slot between the base and the finger. The arm of the lever extends into the slot and engages the finger in response to the movement of the lever to facilitate the insertion and extraction of the circuit board into and from the enclosure.

According to the invention, the lever is coupled to one of the ends of a rotatable rod or camshaft associated with the retainer assembly. A hinge on the lever hingedly couples the lever to the end of the rotatable rod.

In one embodiment, the arm on the lever includes an outer engagement surface and the finger on the bracket includes an interior engagement surface. The outer engagement surface on the arm of the lever engages the inner engagement surface on the finger of the bracket to facilitate the insertion of the circuit board into and from the enclosure.

In one embodiment, a spring element is coupled to either the lever or the camshaft to create a resistance force on the lever. In one embodiment, the spring element is the arm of a clip which is coupled to the lever and the arm engages against the distal end of the camshaft.

In another embodiment, the spring element is a spring pin which is coupled to the lever and the pin exerts a compressive spring force against the distal end of the camshaft. In this embodiment, the distal end of the camshaft defines a groove in which the pin may be seated to keep the lever in a locked position.

In another embodiment, a clip is coupled to the distal end of the camshaft and a detent on the clip engages against an interior surface of the hinge. In still another embodiment, a clip is coupled to the distal end of the camshaft and includes an arm which engages and exerts a compressive spring force against an outer surface of the hinge on the lever.

There are other advantages and features of this invention which will be more readily apparent from the following detailed description of the embodiments of the invention, the drawings, and the appended claims.

### BRIEF DESCRIPTION OF THE DRAWINGS

These and other features of the invention can best be understood by the following description of the accompanying drawings as follows:

FIG. 1 is a perspective view of an electronic circuit board enclosure including two representative printed circuit boards retained therein using four circuit board retainer assemblies, each of the retainer assemblies including a lever assembly in accordance with the present invention;

FIG. 2 is an exploded perspective view of one of the four circuit board retainer assemblies shown in FIG. 1;

FIG. 3 is a broken, part vertical cross-sectional view, part side elevational view of two of the circuit board retainer assemblies shown in their respective unlocked and locked positions in the channel of the enclosure;

FIG. 4 is a front perspective view of a lever in accordance with the present invention;

FIG. 4A is an enlarged broken side elevational view of the arm of the lever shown in FIG. 4;

FIG. 5 is a back perspective view of the lever shown in FIG. 4;

FIG. 6 is an exploded perspective view of the bracket of the lever assembly of the present invention;

FIG. 7 is a partially broken, exploded perspective view of a printed circuit board with respective top and bottom lever assemblies in accordance with the present invention and associated retainer assemblies therein in their pre-insertion position;

FIG. 8A is a partially broken perspective view of the circuit board shown in FIG. 7 and associated top and bottom lever assemblies in their initial insertion and fully unlocked positions in the enclosure;

FIG. 8B is a partially broken perspective view of the circuit board shown in FIG. 7 in an intermediate insertion position in the enclosure;

FIG. 8C is a partially broken perspective view of the circuit board shown in FIG. 7 in an initial locking position in the enclosure;

FIG. 8D is a partially broken perspective view of the circuit board shown in FIG. 7 in an intermediate locking position in the enclosure;

FIG. 8E is a partially broken perspective view of the circuit board shown in FIG. 7 in another intermediate locking position in the enclosure;

FIG. 8F is a partially broken perspective view of the circuit board shown in FIG. 7 in a fully locked position in the enclosure;

FIG. 9A is a partially broken, top plan view of the lower circuit board retainer assembly in its FIG. 8A position in the enclosure;

FIG. 9B is a partially broken, top plan view of the lower circuit board retainer assembly in its FIG. 8B position in the enclosure;

FIG. 9C is a partially broken, top plan view of the lower circuit board retainer assembly in its FIG. 8C position in the enclosure;

FIG. 9D is a partially broken, top perspective view of the lower circuit board retainer assembly in its FIG. 8D position in the enclosure;

FIG. 9E is a partially broken, top perspective view of the lower circuit board retainer assembly in its FIG. 8E position in the enclosure;

FIG. 9F is a partially broken, top perspective view of the lower circuit board retainer assembly in its FIG. 8F position in the enclosure;

FIG. 10 is a front perspective view of one embodiment of a spring loaded lever in accordance with the present invention;

FIG. 11 is a back perspective view of the spring loaded lever of FIG. 10;

FIG. 12 is an enlarged front perspective view of the clip of the spring-loaded lever of FIG. 10;

FIG. 13 is a back perspective view of the clip of the spring-loaded lever of FIG. 10;

FIG. 14 is a partially broken, part cross-sectional, front perspective view of the spring-loaded lever of FIG. 10 in one of its insertion or extraction positions on the distal end of the camshaft of a circuit board retainer assembly;

FIG. 15 is a partially broken, part cross-sectional, top plan view of the spring-loaded lever of FIG. 10 in a locked position on the distal end of the camshaft of a circuit board retainer assembly;

FIG. 16 is another partially broken, part cross-sectional, front perspective view of the spring-loaded lever of FIG. 10 in its initial extended insertion or fully extracted position on the distal end of the camshaft of a circuit board retainer assembly;

FIG. 17 is a back perspective view of another embodiment of a spring loaded lever in accordance with the present invention;

FIG. 18 is a partially broken, part cross-sectional, front perspective view of the spring-loaded lever of FIG. 17 in one of its insertion or extraction positions on the distal end of the camshaft of a circuit board retainer assembly;

FIG. 19 is a partially broken, part cross-sectional, top plan view of the spring-loaded lever of FIG. 17 in a locked position on the distal end of the camshaft of a circuit board retainer assembly;

FIG. 20 is a perspective view of yet another embodiment of a spring loaded lever in accordance with the present invention;

FIG. 21 is a partially broken, part cross-sectional, perspective view of the spring loaded lever of FIG. 20 in one of its insertion or extraction positions on the distal end of a camshaft of a circuit board retainer assembly;

FIG. 22 is a partially broken, part cross-sectional, top plan view of the spring loaded lever of FIG. 20 in a locked position on the distal end of a camshaft of a circuit board retainer assembly;

FIG. 23 is a broken perspective view of a camshaft of a retainer assembly for use with a further embodiment of a spring-loaded lever in accordance with the present invention;

FIG. 24 is a perspective view of the clip shown in FIG. 23;

FIG. 25 is a partially broken, part cross-sectional, perspective view of a lever in one of its insertion or extraction positions on the distal end of the camshaft of FIG. 23;

FIG. 26 is a broken top plan view of the spring loaded lever of FIG. 25 in a locked position on the distal end of the camshaft of FIG. 23;

FIG. 27 is a perspective view of another embodiment of a camshaft of a retainer assembly for use with a still further spring-loaded lever embodiment in accordance with the present invention;

FIG. 28 is an enlarged perspective view of the clip shown in FIG. 27;

FIG. 29 is a partially broken, part cross-sectional, front perspective view of a spring-loaded lever in one of its insertion or extraction positions on the distal end of the camshaft shown in FIG. 27; and

FIG. 30 is a partially broken, top plan view of the spring-loaded lever shown in FIG. 29 in a locked position on the distal end of the camshaft of FIG. 27.

### DETAILED DESCRIPTION OF THE INVENTION

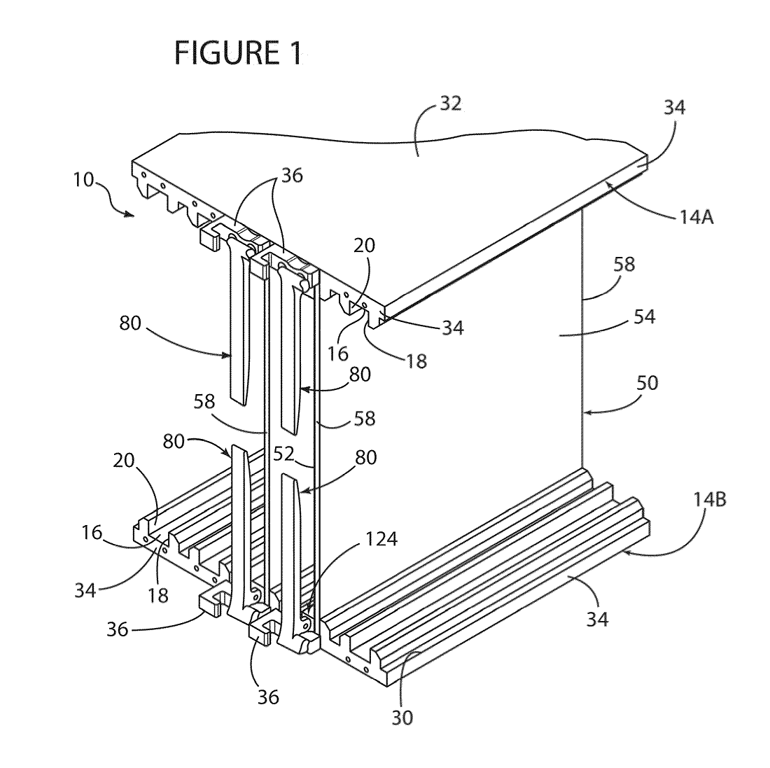

An electronic housing assembly or structure 10 is shown in FIG. 1 which comprises a top cold plate 14A and a bottom cold plate 14B. In the embodiment shown, each of the cold plates 14A and 14B is generally rectangular in shape and includes a plurality of surfaces including an outer surface 32, an interior surface 30, and four exterior side surfaces 34. Cold plates 14A and 14B can be formed from a wide variety of materials that exhibit superior heat conducting abilities including, for example, aluminum, brass, or bronze.

Each of the cold plates 14A and 14B defines a plurality of generally elongated, rectangular, spaced-apart and parallel grooves or channels 16 defined by spaced-apart and parallel walls 18 and 20 protruding generally normally outwardly from the interior surface 30 of each of the cold plates 14A and 14B and extending longitudinally along the length of each of the cold plates 14A and 14B between the front and back side surfaces 34. The channels 16 in opposed cold plates 14A and 14B are disposed in a co-linear and diametrically opposed relationship.

Each of the cold plates 14A and 14B further includes a plurality of spaced-apart, co-linear hooks, brackets or latches 36 that are coupled to and extend outwardly from the front side surface or face 34 of respective cold plates 14A and 14B. Each of the brackets 36 (also see FIG. 6) has an elongate connecting base or plate 40 including an outer camming or engagement surface 35, an arm 37 extending generally normally outwardly from a distal end of the base 40, and a finger 38 extending generally normally upwardly from the end of the arm 37 opposite the end thereof coupled to base 40.

Finger 38 is spaced from and parallel to the connecting base 40 and includes an interior camming or engagement surface 39. A slot is defined in the bracket 36 between the base 40 and the finger 38. A pair of spaced-apart apertures 43 extend through the base 40. A fastener, such as the screw or bolt 41 shown in FIG. 6, extends through each of the apertures 43 to secure the bracket 36 to the outside surface 34 of each of the cold plates 14A and 14B as shown in FIG. 1.

A plurality of generally rectangularly-shaped printed circuit boards 50 (only two of which are representatively shown in FIG. 1) are adapted to be slid into and mounted between respective cold plates 14A and 14B. Printed circuit board 50 can be a conventional multi-layer printed circuit board that has a variety of electronic components mounted thereon. As shown in FIGS. 1, 3 and 7, printed circuit board 50 has opposed front and back faces 52 and 54 (FIGS. 1 and 3), a pair of generally parallel opposed top and bottom longitudinally extending horizontal edges 56 and a pair of generally parallel opposed front and back vertical edges 58 (FIGS. 1 and 7).

Each circuit board 50 includes a pair of circuit board retainer assemblies 124 coupled thereto, i.e., a first retainer assembly 124 coupled to surface 52 and extending along the top longitudinal edge 56 of the circuit board 50 and a second retainer assembly 124 coupled to surface 52 and extending along the bottom longitudinal edge 56 of the circuit board 50.

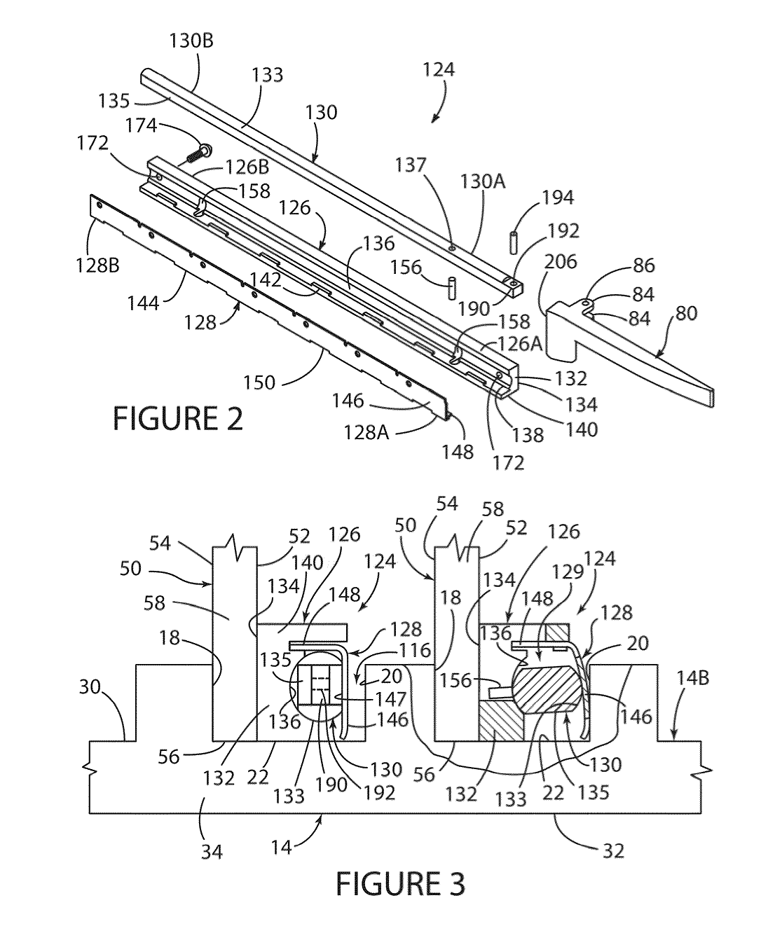

A retainer assembly 124 is depicted in detail in FIGS. 2 and 3 and comprises a generally L-shaped body or housing 126 which holds a spring or resilient element 128 and a rotatable camshaft or rod 130. Body 126 includes a distal end 126A, a proximal end 126B, and a side wall 132 which defines an outer clamping face 134 and an inner concave camshaft contact surface 136.

A continuous slot 138 (FIG. 2) is defined in and extends the full length of side wall 132 and through contact surface 136. Body 126 has a base 140 that extends outwardly from side wall 132 in a direction opposite clamping face 134. A plurality of protrusions or tabs 142 project outwardly from an interior face of base 140 and extend along the length of base 140 in a spaced-apart and co-linear relationship. Body 126 further defines a pair of oval-shaped apertures or recesses 158 that extend through base 140 and contact surface 136 and extend between and through side wall 132 and clamping face 134.

A pair of threaded apertures 172 are defined in contact surface 136 and extend between and through side wall 132 and clamping face 134. A fastener such as a screw or bolt 174 is adapted to extend through circuit board 50 and each of the threaded apertures 172 in body 126 to couple and secure the body 126 to the surface 52 of circuit board 50. Body 126 can be formed from a wide variety of materials that exhibit superior heat conducting abilities such as, for example, aluminum.

A generally L-shaped spring or resilient element 128 includes a distal end 128A and a proximal end 128B. Resilient element 128 can be formed from a sheet of resilient or spring material which is formed with a longitudinally extending bend 144. Bend 144 defines two longitudinal portions which extend away from each other in a generally L-shaped configuration. Resilient outer face portion 146 is adapted to engage the wall 20 of each of the grooves 16 defined in cold plates 14A and 14B under the urging of camshaft 130 as shown in FIG. 3.

Foot portion 148 of spring element 128 is received in slot 138 of body 126 and defines a plurality of spaced-apart ports or openings 150 extending longitudinally along the bend 144 of spring element 128 and fitted in respective tabs 142 on body 126 to partially retain the spring 128 in operable association with body 126. Body 126 and resilient element 128 define a generally rectangularly-shaped bore region 129 (FIG. 3) between camshaft 130 and element 128. Resilient element 128 can be formed from a wide variety of materials that exhibit superior heat conducting abilities such as aluminum.

Rotatable elongated camshaft 130 has a distal end 130A and a proximal end 130B. Camshaft 130 has a non-circular, generally oval-shaped cross-section. Camshaft 130 has diametrically opposed rounded camming surfaces or lobes 133 and diametrically opposed flat portions or surfaces 135. Camshaft 130 can be formed from a wide variety of materials that exhibit superior heat conducting abilities such as aluminum.

A pin 156 is press-fit into an aperture 137 defined in camshaft 130 and is adapted to be received in recess 158 in body 126. Pin 156, in combination with recess 158, limits the extent of the rotation of the camshaft 130 to approximately ninety degrees or one-quarter of a revolution.

Retainer assembly 124 is in its narrowest configuration when camshaft 130 is rotated so that its minor axis extends between contact surface 136 of body 126 and resilient face portion 146 of spring element 128. As camshaft 130 is rotated through approximately 90°, its major axis is brought into a position where it extends between the contact surface 136 of body 126 and the resilient face portion 146 of spring element 128.

As camshaft 130 is rotated from an unlocked position (FIG. 3, left side) to a locked position (FIG. 3, right side) in which the portion 146 of spring element 128 is abutted and wedged against the wall 20 of enclosure 10, the longitudinal axis shifts towards the resilient face portion 146 of spring element 128. Therefore, the amount by which resilient face portion 146 of spring element 128 is deflected outwardly is greater than the difference between the lengths of the major and minor axes.

The outward shift or translation of the longitudinal axis of camshaft 130 occurs due to contact surface 136 of body 126 being shallow at its midpoint. The radius of contact surface 136 is such that in the unlocked position, camshaft 130 is retained within the retainer assembly 124. The radius of contact surface 136 at its midpoint is large as compared to its endpoints. It is noted that camshaft 130 is not journaled or retained by bearings. This allows camshaft 130 to shift freely responsive to the action of contact surface 136.

The relationship between face portion 146 and foot portion 148 on resilient element 128 is such that, when coupled to the body 126, there is a spring tension against the camshaft 130 which holds the camshaft 130 in the desired operable position within bore 129.

In the locked position with the major axis of camshaft 130 extending between contact surface 136 of body 126 and face portion 146 of spring element 128, the face portion 146 extends outwardly beyond camming surface 133 of camshaft 130. This deflection is sufficient to maintain spring tension and firmly clamp face 134 against circuit board edge 56 even when the assembly 10 becomes heated and the respective parts of the retainer assembly 124 expand at different rates. Because the body 126, resilient element 128, and camshaft 130 are substantially coextensive throughout the length of the groove 16, the clamping forces are substantially uniform along the entire length of circuit board edge 56.

The retainer assembly 124 described above and shown in FIGS. 2 and 3 is the subject of U.S. Pat. No. 5,200,882, the contents of which are incorporated herein by reference.

Distal end 130A of camshaft 130 has a flat, generally square-shaped distal end portion or face 190 having an aperture 192 extending therethrough and adapted to receive a lever 80 in accordance with the present invention.

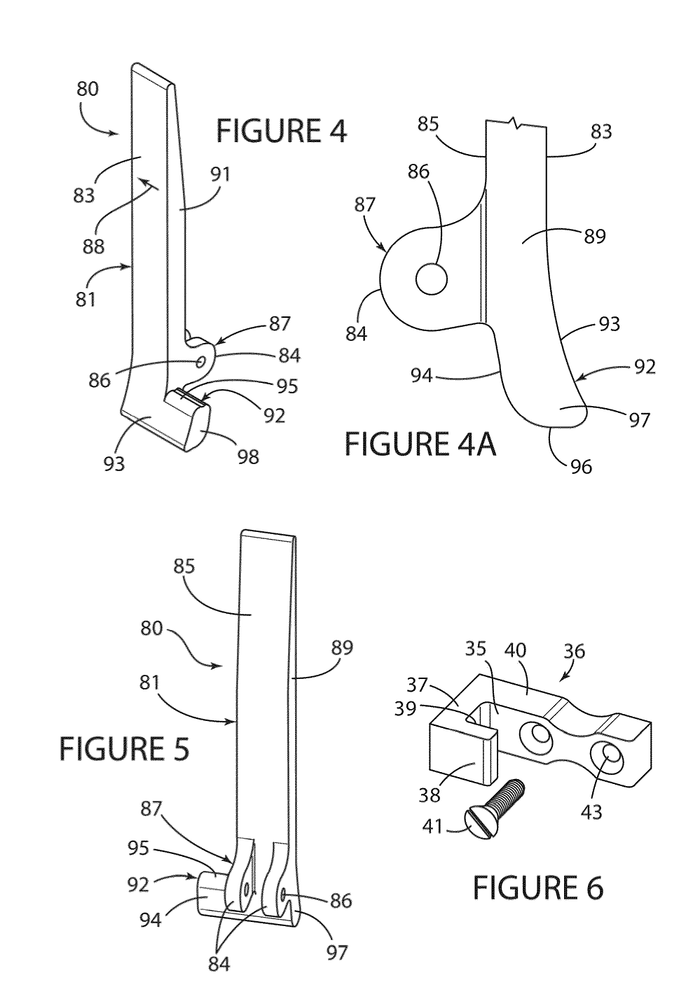

Lever 80, as shown in FIGS. 4, 4A, and 5, includes a handle 81 with an outer surface 83, an inner surface 85, opposed side surfaces 89 and 91, and an arm or head or projection 92 extending generally normally outwardly from a distal lower end portion of one of the side surfaces 91. A hinge 87 is defined by a pair of spaced-apart, parallel brackets 84 which protrude normally outwardly from a portion of the interior face 85 of lever 80 located adjacent and above the arm 92. The outside face of respective brackets 84 is co-planar with respective lever side surfaces 89 and 91. An aperture 86 extends through each of the brackets 84 in an orientation generally parallel to the lever front and back surfaces 83 and 85. Apertures 86 are generally co-linear.

Lever 80 is attached to camshaft 130 by a pin 194 in a relationship wherein the flat distal end portion 190 on distal end 130A of camshaft 130 is captured between the brackets 84 and the pin 194 is press fit into and extends through the aligned apertures 86 in the brackets 84 and camshaft 130 respectively. Lever 80 is thus rotatable and pivotable about the distal end portion 190 and distal end 130A of camshaft 130 in an orientation and relationship generally co-planar with the longitudinal axis and plane of camshaft 130.

Arm 92 includes a plurality of camming or engagement surfaces including an outer camming or engagement surface 93, an opposed inner camming or engagement surface 94, an upper camming or engagement surface 95 and an opposed lower camming or engagement surface 96. Arm 92 additionally includes opposed end surfaces 97 and 98.

Surface 93 is contiguous with and curves outwardly and away from the outer surface 83 of lever 80. Surface 94 is contiguous with and curves outwardly and away from the inner surface 85 of the lever 80. Surfaces 93 and 94 are generally parallel to each other. End surface 97 is generally flat and contiguous and co-planar with a lower portion of lever side surface 89.

Lever 80 is a dual function lever. Lever 80 can be pushed and pulled and rotated in both clockwise and counter-clockwise directions. Lever 80 and, more specifically, the handle 81 thereof, is adapted to be grasped by the hand of a user and turned or rotated to cause the rotation of camshaft 130 and the locking and/or unlocking and/or insertion/extraction of the board 50 to and from the housing 10 as described in more detail below. Lever 80 allows a user to apply a sufficient amount of leverage to readily rotate camshaft 130 using only hand power.

Lever 80 may include indicia 88 (FIG. 4) such as an arrow or wording to indicate the direction of rotation that lever 80 is to be rotated to lock circuit board 50 to cold plates 14A and 14B. Lever 80 can be rotated either clockwise (for the top retainer assembly 124) or counterclockwise (for the bottom retainer assembly 124) in order to lock retainer assembly 124 in plates 14A and 14B.

Retainer assemblies 124 are secured to the circuit board 50 and the levers 80 thereon are operable to allow the insertion and locking of the circuit board 50 to the electronic housing assembly 10 as described in more detail below:

1. Initially, lever 80 is attached to camshaft 130 by wedging the flat distal end portion 190 at the distal end 130A of camshaft 130 between brackets 84 of lever 80 and then pressing pin 194 through the respective apertures 86 in brackets 84 and the aperture 192 in the flat distal end face 190 of camshaft 130.

2. Retainer assembly pins 156 are inserted through and press-fit into apertures 137 in camshaft 130.

3. Foot portion 148 of resilient element 128 is inserted into slot 138 of retainer body 126. Openings 150 in resilient element 128 are placed over protrusions 142 on retainer body 126.

4. Camshaft 130 is slid between retainer body 126 and resilient element 128 until flat portion or surface 135 of camshaft 130 snaps into position into alignment between resilient portion 146 of resilient element 128 and contact surface 136 of retainer body 126 to complete the retainer assembly 124.

5. A retainer assembly 124 is attached to both the top and bottom longitudinal edges 56 of circuit board 50 using fasteners 174 that are threaded into apertures 172 in retainer body 126 and then threaded into respective apertures (not shown) in the interior surface 52 of circuit board 50.

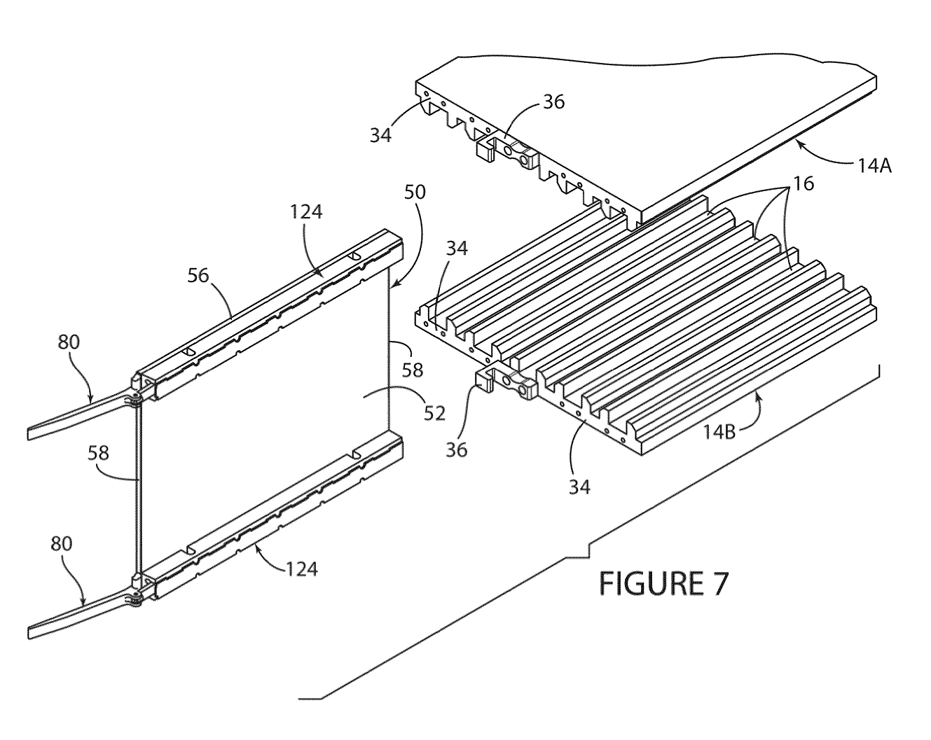

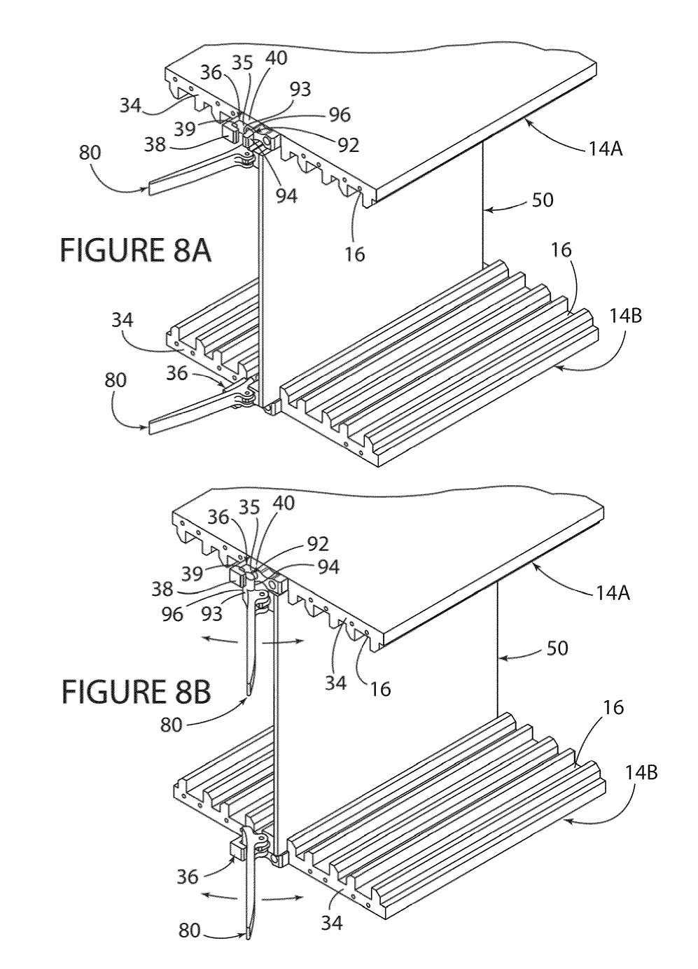

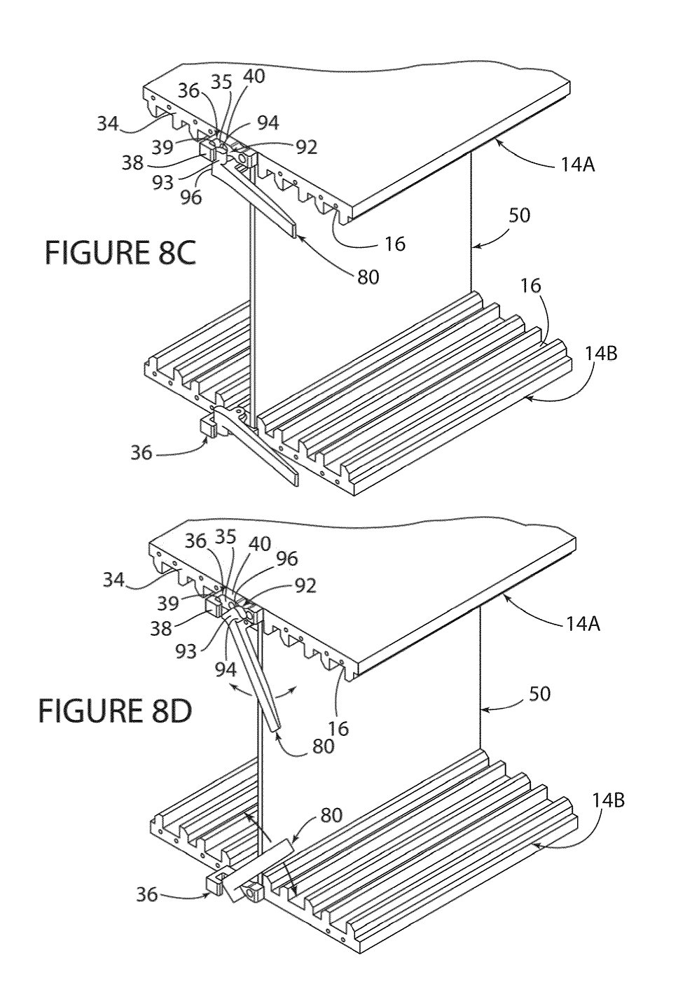

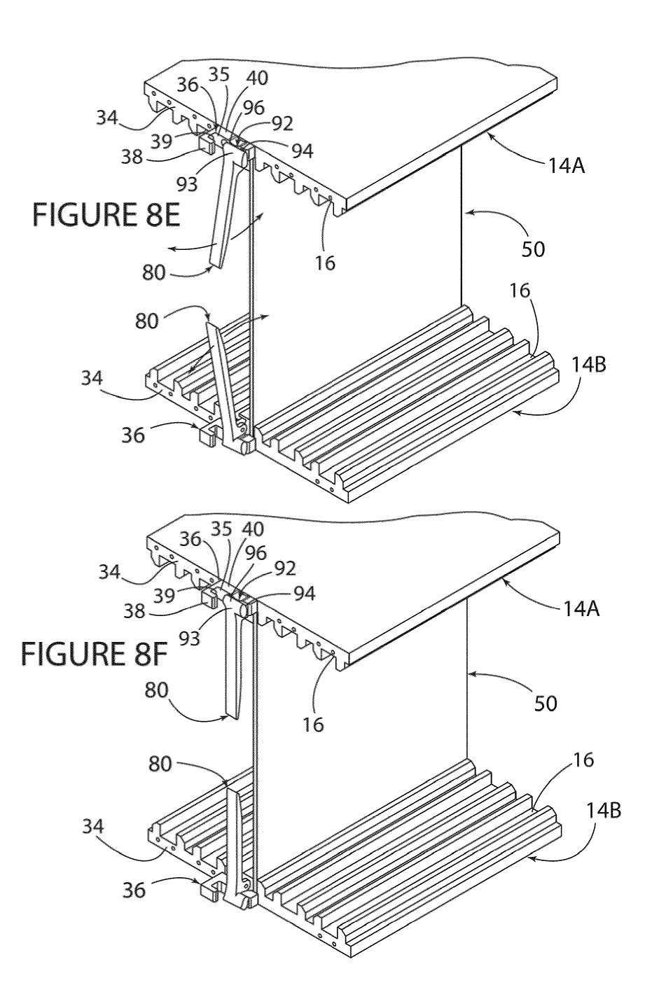

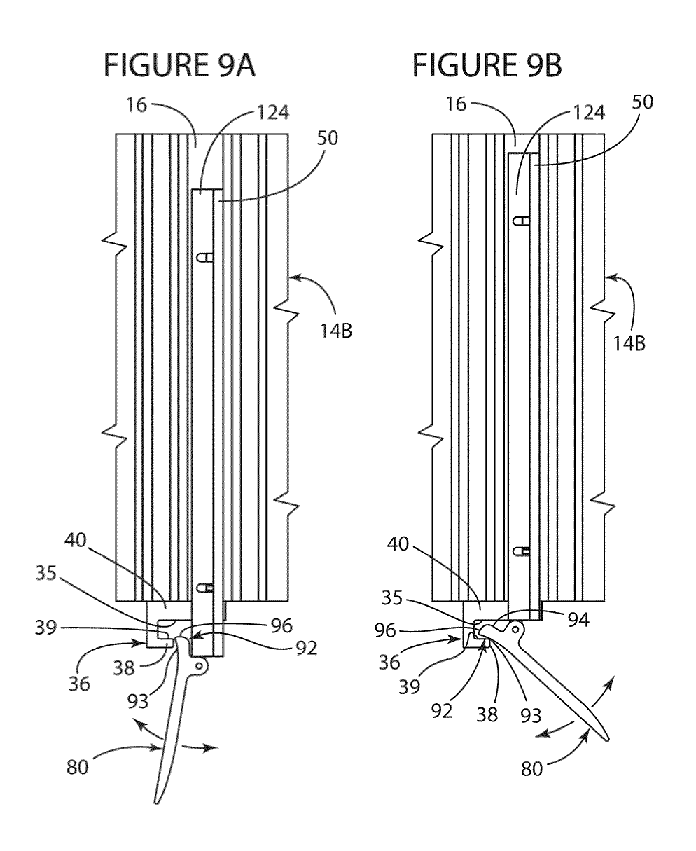

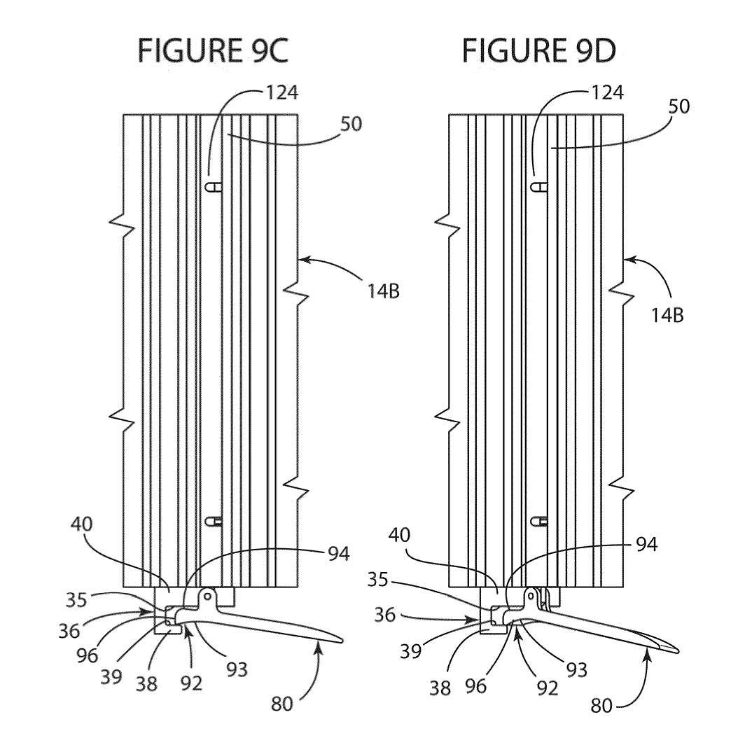

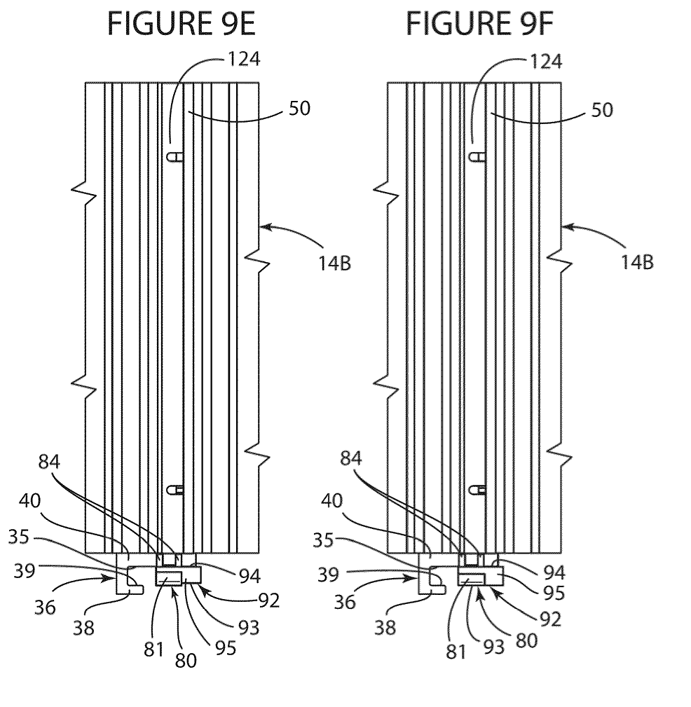

6. The levers 80 are then grasped by the handles 81 thereof and the circuit board 50 is slid into one of the respective pair of opposed channels 16 in cold plates 14A and 14B into the initial insertion and unlocked position of FIGS. 8A and 9A wherein the levers 80 thereof are oriented and positioned in an extended position and relationship generally parallel to the circuit board 50; generally normal to the front edge 34 of respective cold plates 14A and 14B; and generally co-linear with the longitudinal axis of camshaft 130 and retainer assembly 124.

7. The levers 80 are then pushed and rotated inwardly in a counter-clockwise direction about pin 194 and distal end portion 190 of camshaft 130 in the direction of and toward the circuit board 50 as shown in FIGS. 8B and 9B causing the arm 92 to extend into the slot defined between the base 40 and finger 38 of bracket 36 and, more specifically, causing the outside surface 93 on arm 92 to engage with the interior engagement surface 39 on the finger 38 of bracket or latch 36.

8. Turning now to FIGS. 8C and 9C, the continued pushing of levers 80 counter-clockwise inwardly in the direction of circuit board 50 with arm 92 engaged against the bracket finger 38 causes retainer assemblies 124 and thus circuit board 50 to be pulled, slid, and moved further inwardly into the assembly 10.

9. The still continued pushing of the levers 80 counter-clockwise inwardly into a position wherein the levers 80 are oriented in a relationship generally parallel to the front edge 34 of cold plates 14A and 14B causes retainer assemblies 124 and circuit board 50 to be fully inserted in plates 14A and 14B and thus in assembly 10. The position shown in FIGS. 8C and 9C corresponds to a fully inserted and initial locking position of circuit board 50.

10. Bottom lever 80 is then subsequently rotated upwardly in a counter-clockwise direction and top lever 80 is rotated downwardly in a clockwise direction as shown in FIGS. 8D and 9D to cause the rotation of camshaft 130 and, more specifically, to cause camshaft surface 133 of respective retainer assemblies 124 to force the resilient element 128 of respective retainer assemblies 124 into contact with the wall 20 of respective cold plates 14A and 14B to lock the retainer assembly 126 and thus the circuit board 50 in assembly 10.

11. Respective top and bottom levers 80 are rotated respectively clockwise and counterclockwise a distance of a total of 90° from the position of FIGS. 8D and 9D to the position of FIGS. 8E and 9E into a position and orientation in which the levers 80 are positioned and oriented generally co-planarly with the circuit board 50 and the interior engagement surface 94 of arm 92 thereof is engaged with and against the exterior surface 35 of the base 40 of respective brackets 36. Next, the levers 80 are pushed inwardly in the direction of the circuit board 50 from the position of FIGS. 8E and 9E to the fully locked position shown in FIGS. 8F and 9F where the levers 80 remain positioned and oriented in a relationship generally parallel with the circuit board 50 and normal to the respective cold plates 14A and 14B and the interior surface 94 of arm 92 of respective levers 80 is engaged against the exterior surface 35 of the base 40 of respective brackets 36.

Circuit board 50 can be removed or extracted from assembly 10 as described in detail below with reference to the action of bottom lever 80 and bottom retainer assembly 124 by simply reversing the insertion and locking steps described above and incorporated herein by reference and further as described below in more detail:

1. Levers 80 are initially pulled outwardly away from the circuit board 50 and enclosure 10 from their fully locked positions of FIGS. 8F and 9F as described above in detail back to their initial unlocking position of FIGS. 8E and 9E as also described above in detail.

2. Bottom lever 80 is then rotated clockwise 90° and top lever 80 is rotated 90° counter-clockwise from the FIGS. 8E and 9E positions to their fully unlocked and initial extraction positions of FIGS. 8C and 9C as also described above in detail into a position in which the levers 80 are disposed in a relationship generally normal to the circuit board 50 and parallel to the respective cold plates 14A and 14B. In this position, the arm 92 of respective levers 80 is located in the slot of respective brackets 36.

3. Levers 80 are then pulled outwardly in a direction away from the circuit board 50 and enclosure 10 and rotated in a clockwise direction about the pin 194 and distal end portion 190 of camshaft 130 into the position shown in FIGS. 8B and 9B causing interior engagement surface 94 of arm 92 to engage against the exterior extraction engagement surface 35 on the base 40 of bracket or latch 36 and the exterior surface 93 of arm 92 to engage against the interior surface 39 on the finger 38 of bracket 36. The engagement between the respective lever arm surfaces and bracket surfaces pulls the circuit board 50 and respective retainer assemblies 124 outwardly out of the assembly 10.

4. The continued pulling of levers 80 outwardly from their FIGS. 8B and 9B position to their FIGS. 8A and 9A position causes retainer assembly 124 and circuit board 50 to be pulled, slide, and move further outwardly out of assembly 10 back into its FIGS. 8A and 9A position as described earlier in detail.

### Spring Lever Embodiments

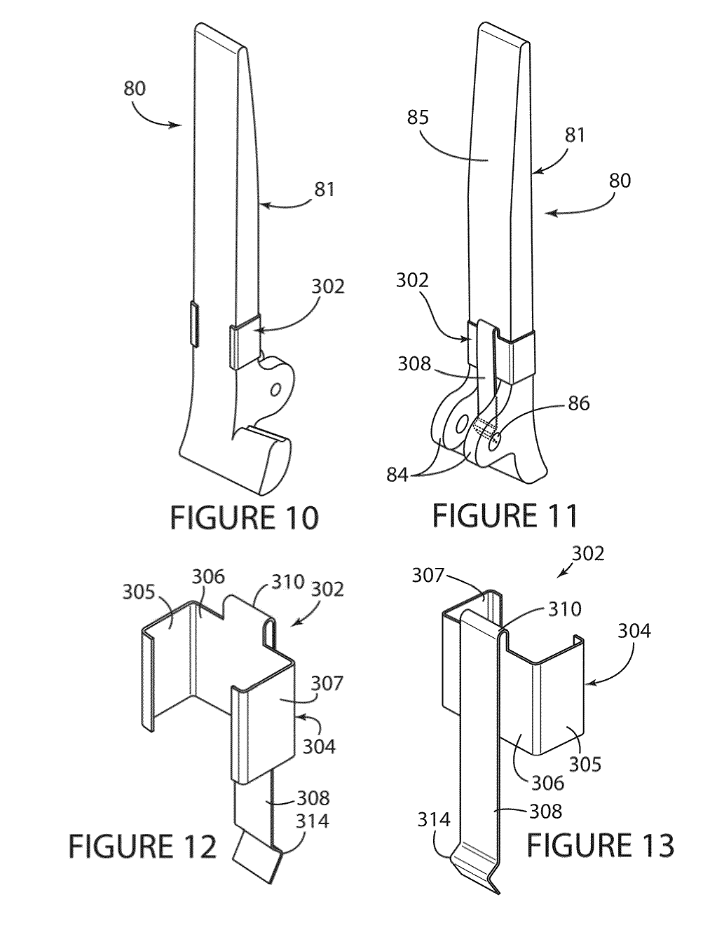

FIGS. 10-30 depict five different spring mechanisms or elements adapted to be incorporated onto either the lever 80 or the camshaft 130 of the retainer assembly 126 to create a spring resistance force on the lever 80 which biases the lever 80 against the retainer 124 and camshaft 130.

FIGS. 10-16 depict a lever 80 which is identical in all respects to the lever 80 described above with respect to FIGS. 1-9 except that a spring or clip 302 is clipped to the lever 80 to create a spring-loaded lever 80.

Clip 302 includes a generally U-shaped body or bracket 304 defined by opposed, spaced-apart, parallel side walls 305 and 307 and a center wall 306 therebetween. Clip 302 also comprises an elongate spring arm 308 which extends from bracket 304 and includes a generally U-shaped bend 310 which is coupled to and extends upwardly from the top peripheral edge of bracket center wall 306 and then downwardly to cause the arm 308 to extend down from the bracket 304 in a relationship spaced from and parallel to the front surface of bracket center wall 306. The distal end of elongate arm 308 terminates below the bracket 304 in a curved detent or ear 314. Clip 302 can be formed from spring sheet metal.

Clip 302 is clipped to the handle 81 of lever 80 just above the lever hinge brackets 84 thereof in a relationship wherein the clip bracket 304 surrounds the lever 80, the center wall 306 of clip bracket 304 is abutted against the interior face 85 of lever 80, and the elongate clip arm 308 extends downwardly into the space defined between the two lower hinge brackets 84 and is positioned in a relationship spaced from and parallel to the interior surface 85 of lever 80.

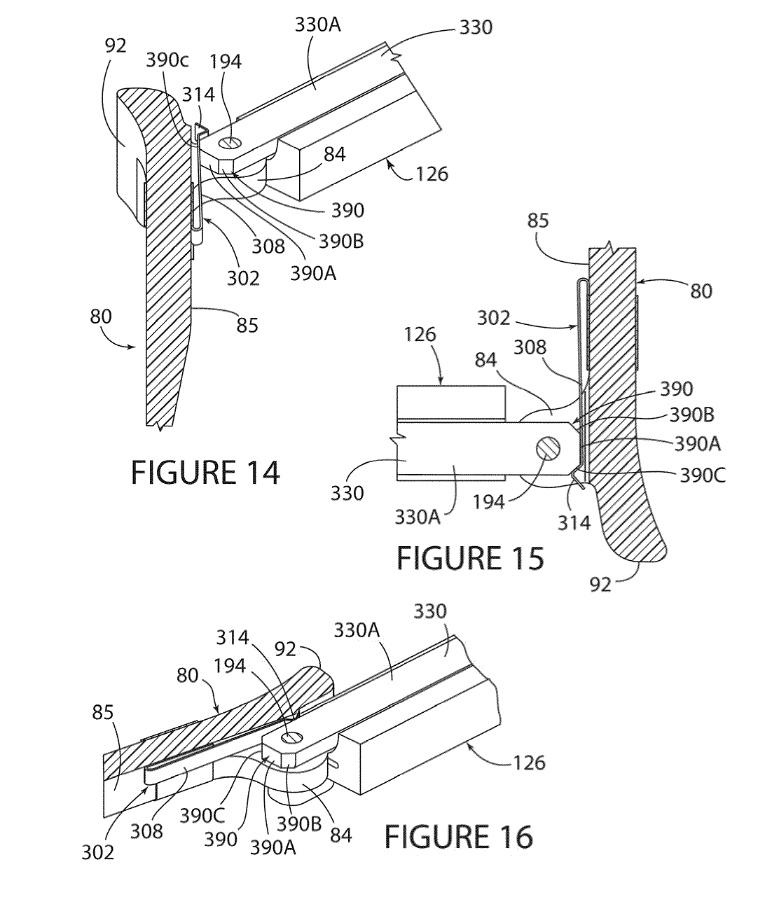

The lever 80 with clip 302 is coupled to the flat distal end portion 390 at the distal end 330A of camshaft 330 in the same manner as described above with respect to camshaft 130. Camshaft 330 is similar in structure to camshaft 130 except that the camshaft 330 shown in FIGS. 14-16 includes a flat distal end portion 390 which includes a peripheral outer flat center end surface 390A and two peripheral outer opposed flat end or corner surfaces 390B and 390C extending inwardly from the opposed ends of the center end surface 390A at 45° angles respectively.

Specifically, lever 80 is coupled to camshaft 330 in a relationship wherein the distal end of the arm 308 of clip 302 and, more specifically, the outside surface thereof, is abutted against one of the peripheral outer end surfaces 390A, 390B, or 390C on the distal end portion 390 of camshaft 330 depending upon the position of lever 80 relative to the camshaft 330.

In the position where the lever 80 is positioned in an orientation generally normal to the distal end 330A of camshaft 330, the outside surface of the distal end of clip arm 308 is abutted and exerts a compressive spring force against the outer center distal end surface 390A of camshaft 330 and the detent or ridge 314 of clip arm 308 is abutted and exerts a compressive spring force against the flat angled corner distal end surface 390C of camshaft 330 and lever 80 to keep the lever 80 biased and spring-loaded in the locked position of FIGS. 8F and 9F until lever 80 is manually grasped and unlocked.

In the FIGS. 14 and 16 positions where the lever 80 is either at a 45° angle relative to the distal end 330A of the camshaft 330 (FIG. 14) or generally parallel to the distal end 330A of the camshaft 330 (FIG. 16), the outside face of the distal end of the clip arm 308 is abutted and exerts a compressive spring force against either the angled distal end surface 390C (FIG. 14) or the side surface of camshaft 330 (FIG. 16) again to keep the lever 80 biased and spring-loaded against the camshaft 330 until the lever 80 is grasped by a user.

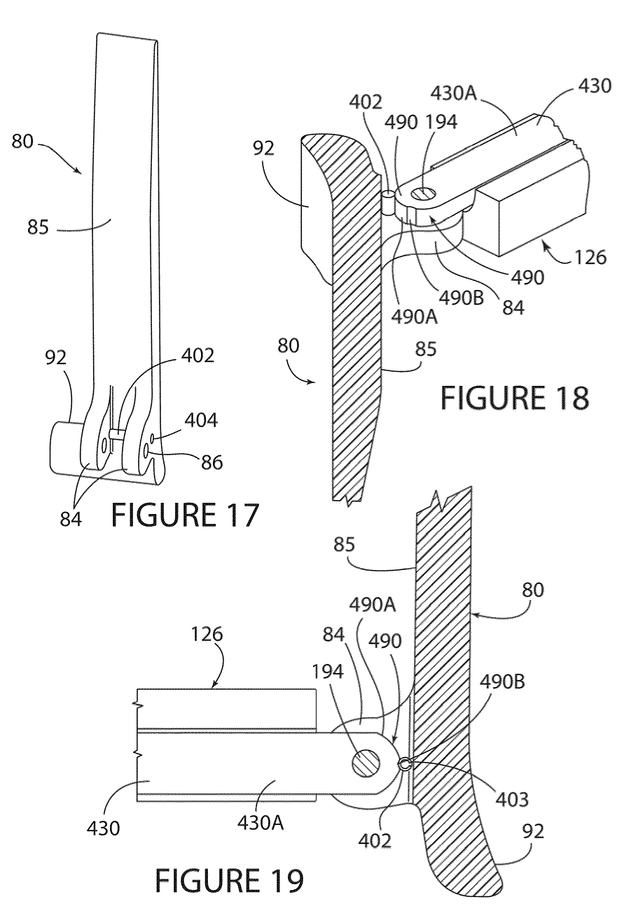

FIGS. 17-19 depict a lever 80 in which the spring action mechanism or element comprises a generally tubular spring pin 402 abutted against the interior surface 85 of lever 80 and extending generally normally in the space defined between the two hinge brackets 84 of lever 80 and including respective opposed ends extending into respective apertures 404 defined in the hinge brackets 84. Spring pin 402 defines an elongate, longitudinal slit 403 (FIG. 19) which allows pin 402 to compress or expand to provide a spring action. Pins 402 may be made from any suitable compressible or expandable material.

The lever 80 is coupled to the flat distal end portion 490 at the distal end 430A of camshaft 430 in the same manner as earlier described into a relationship wherein the spring pin 402 is abutted and exerts a spring compression force against a flat peripheral outer end surface 490A of the distal end portion 490 of camshaft 430 (FIG. 18) to keep the lever 80 biased and spring-loaded against the distal end 430A of camshaft 430 until the lever 80 is grasped by a user; or keep the pin 402 seated in a groove 490B (FIG. 19) defined in the distal peripheral outer end surface 490A on the distal end portion 490 of camshaft 430 to keep the lever 80 biased in its fully locked position of FIGS. 8F and 9F.

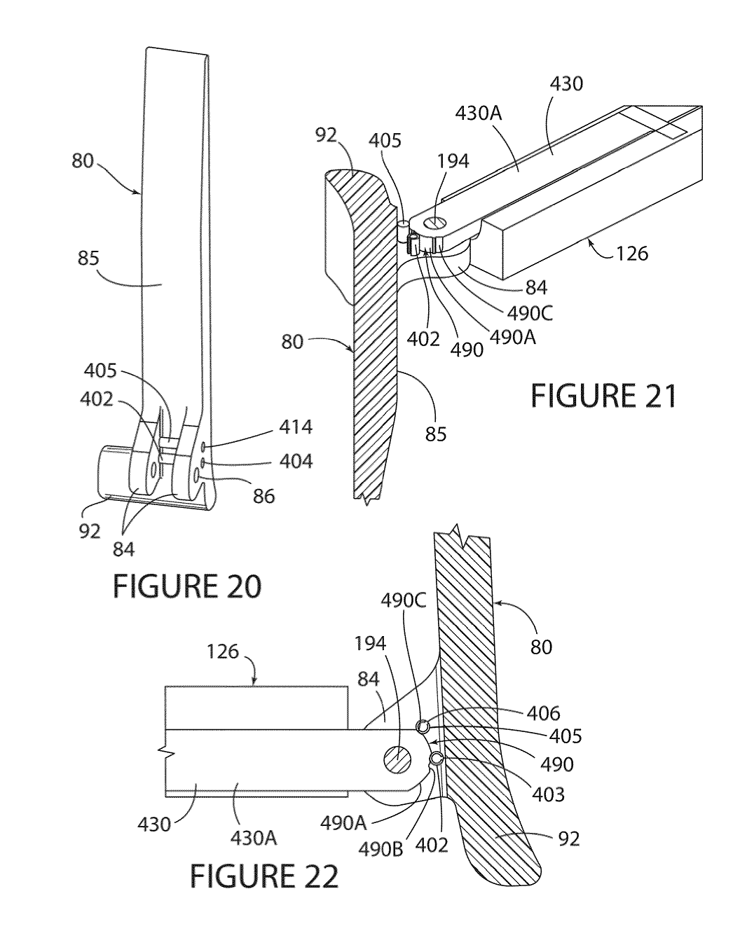

FIGS. 20-22 depict a lever 80 and camshaft 430 which is similar to the lever 80 and camshaft 430 respectively shown in FIGS. 17-19 except that: 1) the lever 80 includes a second elongate tubular spring pin 405 located just above and spaced from and parallel to the spring pin 402 and including respective ends extending through a second set of respective apertures 414 in respective lever hinge brackets 84; and 2) the distal rounded outer peripheral end surface 490A on the distal end portion 490 at the distal end 430A of camshaft 430 defines a central groove 490C adapted to receive pin 402 and additionally defines a corner groove 490C adapted to receive the pin 405 when lever 80 is positioned in its fully locked position of FIGS. 8F and 9F. In the embodiment of FIGS. 20-22, spring pin 405 is also abutted against the interior surface 85 of lever 80 and extends in the space defined between lever bracket 84.

As described above, the pins 402 and 405 are adapted to exert a compressive spring force against the peripheral outer end surface 490A of the distal end portion 490 of camshaft 430 to keep the lever 80 biased and spring-loaded against the camshaft 430. Pins 402 and 405 are also adapted to be received in the respective grooves 490B and 490C defined in the distal end outer peripheral surface 490A of distal end portion 490 of camshaft 430 which, in turn, biases and keeps the lever 80 in its locked position against the distal end surface 490A of camshaft 430 until the lever 80 is grasped by a user.

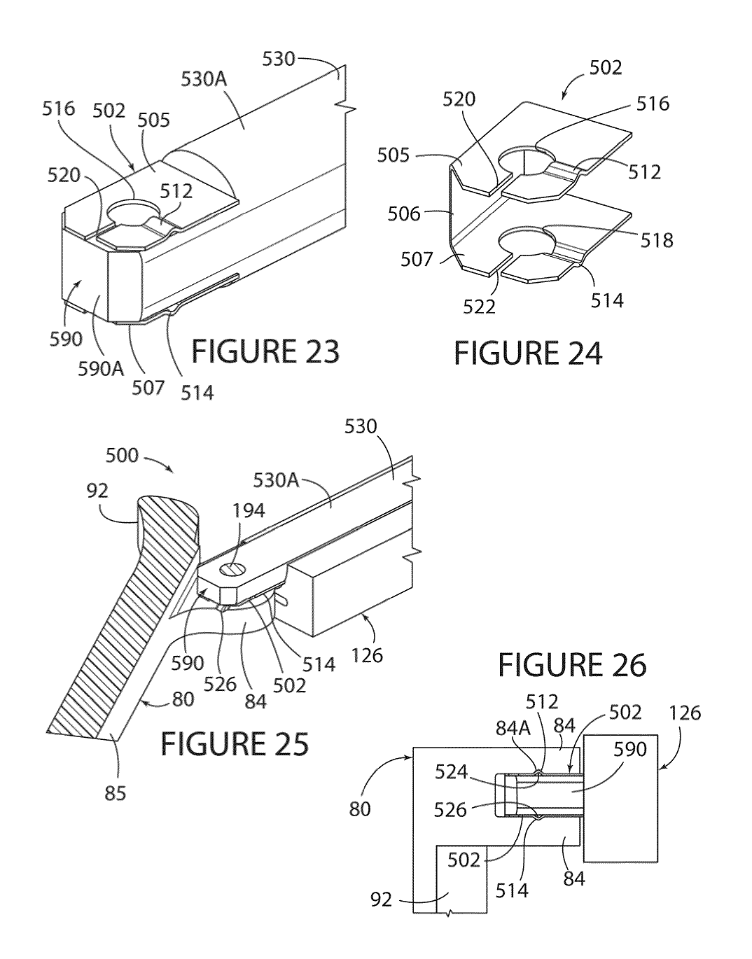

FIGS. 23-26 depict a clip spring structure 502 which is adapted to be clipped to the flat distal end portion 590 on the distal end 530A of camshaft 530.

Clip 502 includes a pair of opposed, spaced-apart, parallel side walls 505 and 507 and a contiguous center wall 506 therebetween together defining an open interior. Each of the side walls 505 and 507 defines a generally centrally located through-opening 516 and 518 respectively and an outwardly projecting and curved ridge or detent 512 and 514 formed in the respective side walls 505 and 507 and extending between the edge of the respective through-openings 516 and 518 and a peripheral outside edge of the respective side walls 505 and 507.

Each of the side walls 505 and 507 further defines a slit 520 and 522 extending between another of the edges of the respective through-openings 516 and 518 and another of the peripheral edges of the respective side walls 505 and 507. The ridges 512 and 514 are disposed in a relationship normal and 90° removed from the slits 520 and 522. The ridges 512 and 514, through-openings 516 and 518, and slits 520 and 522 are respectively diametrically opposed to each other.

In this embodiment, the lever hinge brackets 84 define respective grooves 524 and 526 formed in the respective inwardly facing interior surfaces thereof.

Clip 502 is coupled and clipped to the flat distal end portion 590 at the distal end 530A of camshaft 530 in a relationship wherein the interior surface of respective clip walls 505, 506, and 507 are abutted against respective exterior surfaces of the flat distal end portion 590 at the distal end 530A of camshaft 530, apertures 516 and 518 in clip side walls 505 and 507 are co-linearly aligned with the through-hole (not shown) and the pin 194 extending through distal end portion 590, and the respective slits 520 and 522 in side walls 505 and 507 are located adjacent and generally normal to the outer surface 590A of camshaft distal flat portion 590.

When the lever 80 is coupled to the flat distal end portion 590 at the distal end 530A of camshaft 530, the respective detents 512 and 514 in clip side walls 505 and 507, in a manner similar to the earlier described spring element embodiments, abut against and exert a compressive spring force against the interior surface of each of the hinge brackets 84 and create a lever resistance force which keeps the lever 80 biased against the camshaft 530 until the lever 80 is grasped and manipulated by a user.

Moreover, when the lever 80 is positioned in its locked position of FIGS. 8E, 9F, and 26, the detents 512 and 514 are seated in the respective grooves 524 and 526 defined in the respective hinge brackets 84 to keep the lever 80 in its locked position.

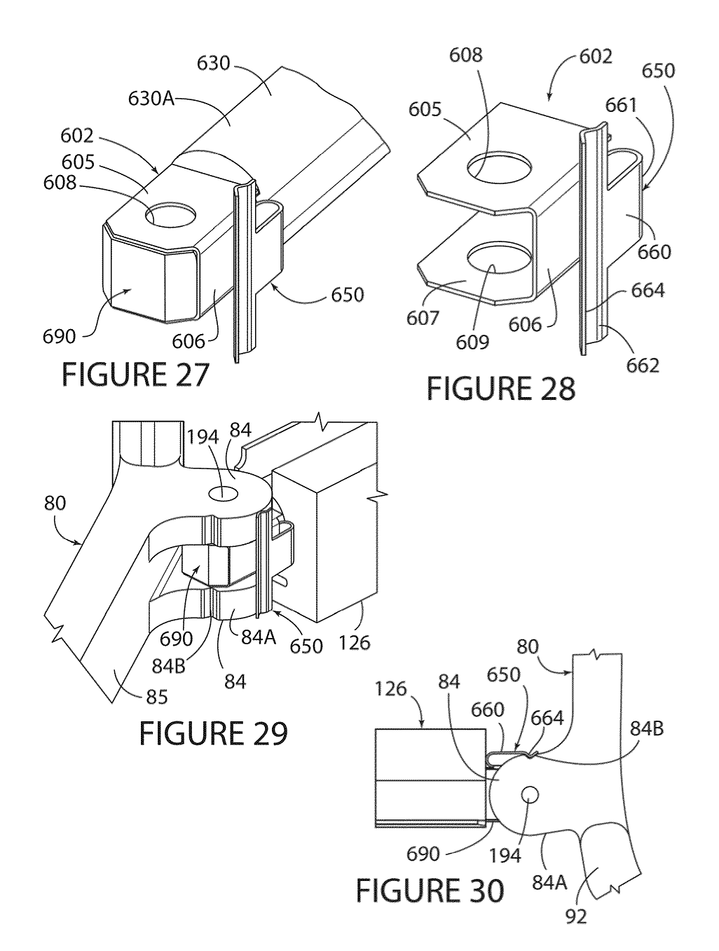

FIGS. 27-30 depict another clip spring structure 602 which is adapted to be clipped onto the flat distal end portion 690 at the distal end 630A of camshaft 630. Clip 602 includes a pair of opposed, spaced-apart, parallel side walls 605 and 607 and a center wall 606 therebetween which is positioned generally normal and contiguous with the side walls 605 and 607 and together define an open interior. Side walls 605 and 607 define respective central circular apertures 608 and 609. Apertures 608 and 609 are diametrically opposed to each other.

Clip 602 also includes a generally T-shaped spring element 650 coupled thereto. Specifically, spring 650 includes an elongate arm 660 which has a U-shaped base or shoulder 661 coupled to and contiguous with a lower edge of clip center wall 606. Arm 660 is positioned in a relationship spaced and parallel to the outer surface of clip center wall 606. An elongate plate 662 extends outwardly from a distal end of the arm 660 in a relationship generally normal to the arm 660 and in a spaced and parallel and opposed relationship to the outer surface of clip center wall 606. Plate 662 defines an elongate distal bend or curve defining a raised detent 664.

Clip 602 is clipped to the flat distal end portion 690 on the distal end 630A of camshaft 630 as shown in FIG. 27 into a relationship in which the interior surfaces of respective walls 605, 606, and 607 of clip 602 are abutted against the exterior surfaces of the flat distal end portion 690 and the apertures 608 and 609 in side walls 605 and 607 are co-linearly aligned with the through-hole (not shown) defined in the flat distal end portion 690 and the arm 660 extends in the direction of the flat distal end portion 690.

As shown in FIGS. 29 and 30, each of the hinge brackets 84 on the lever 80 includes an outer peripheral surface 84A defining a groove 84B extending in the same direction as the apertures 86 extending through each of the hinge brackets 84. Grooves 84B are positioned on an interior portion of the outer surface 84A of respective brackets 84 adjacent the interior 85 of lever 80.

In accordance with the present invention, when the lever 80 is coupled to the distal end 630A of camshaft 630, the plate 662 of clip 602 abuts and exerts a compressive force against the outer surface 84B of respective hinge brackets 84 to create a lever resistance spring force as described above with the earlier spring element embodiments which keeps the lever 80 engaged against the distal end of the camshaft 630. Additionally, when lever 80 is rotated relative to the camshaft 630 into its locked position depicted in FIGS. 8F and 9F and FIG. 30, the detent 664 on the plate 662 of clip arm 660 is seated in the respective grooves 84A in each of the hinge brackets 84 to keep and bias lever 80 in its fully locked position.

### CONCLUSION

While the invention has been taught with specific reference to the above described embodiments, someone skilled in the art will recognize that changes can be made in form and detail without departing from the spirit and the scope of the invention. The described embodiments are to be considered in all respects only as illustrative and not restrictive. For example, it is understood that the lever assembly described above is not restricted for use with the retainer assembly described herein but rather may be used with any other suitable retainer assembly which includes at least a rotatable rod or camshaft. The scope of the invention is, therefore, indicated by the appended claims rather than by the foregoing description. All changes that come within the meaning and range of equivalency of the claims are to be embraced within their scope.

What is claimed is:

1. A lever assembly for use with a retainer adapted to releasably retain a circuit board in an enclosure, the lever assembly comprising:
a rotatable lever including a handle and a distal arm extending outwardly from a distal end of the handle; and
a bracket coupled to the enclosure and adapted to engage with the arm on the lever in response to the movement of the lever to facilitate the insertion and extraction of the circuit board into and from the enclosure.

2. The lever assembly of claim 1 wherein the bracket includes a finger and defines a slot, the arm on the lever engaging the finger and extending into the slot in response to the movement of the lever to facilitate the insertion and extraction of the circuit board into and from the enclosure.

3. The lever assembly of claim 1 wherein the retainer includes a rotatable rod, the lever being coupled to one of the ends of the rotatable rod.

4. The lever assembly of claim 3 further comprising a hinge on the lever for hingedly coupling the lever to the one of the ends of the rotatable rod.

5. The lever assembly of claim 1 further comprising a spring element for creating a resistance spring force on the lever.

6. A lever assembly for use with a retainer assembly adapted to releasably secure a circuit board in an enclosure, the lever assembly comprising:
a lever coupled to one of the ends of a rotatable camshaft associated with the retainer assembly, the lever including an elongated handle and an arm extending generally normally outwardly from a distal end of the handle; and
a bracket coupled to the enclosure, the bracket including a base coupled to the enclosure, a finger spaced from the base, and a slot defined between the base and the finger, the finger defining at least one engagement surface, the arm extending into the slot and engaging the engagement surface on the finger of the bracket in response to movement of the lever to facilitate the insertion and extraction of the circuit board into and from the enclosure.

7. The lever assembly of claim 6 wherein the arm on the lever includes an outer engagement surface and the finger on the bracket includes an interior engagement surface, the outer engagement surface of the arm of the lever engaging the inner engagement surface of the finger of the bracket for facilitating the insertion and extraction of the circuit board into and from the enclosure.

8. The lever assembly of claim 6 wherein the arm on the lever includes an inner engagement surface and the base of the bracket includes an outer engagement surface, the inner engagement surface of the arm on the lever engaging the outer engagement surface of the base of the bracket for facilitating the extraction of the circuit board into and from the enclosure.

9. The lever assembly of claim 6 further comprising a spring element for creating a spring force on the lever.

10. The lever assembly of claim 9 wherein the spring element is a clip coupled to either the lever or the camshaft.

11. An assembly for releasably retaining a circuit board in a circuit board enclosure, the assembly comprising:
a retainer configured to releasably clamp the circuit board in the circuit board enclosure, the retainer including a rotatable camshaft including a distal end;
a lever coupled to the distal end of the camshaft; and
a spring element coupled to the lever or the camshaft.

12. The assembly of claim 11 further comprising a clip coupled to the lever, the clip including an arm defining the spring element, the arm engaging and exerting a compressive spring force against the distal end of the camshaft.

13. The assembly of claim 11 wherein the spring element is defined by a spring pin coupled to the lever, the distal end of the camshaft defining a groove, the spring pin adapted to engage against the distal end of the camshaft and be seated in the groove defined in the distal end of the camshaft.

14. The assembly of claim 11 wherein the lever includes at least one hinge for coupling the lever to the distal end of the camshaft, the hinge including an interior surface defining a groove, the assembly further comprising a clip coupled to the distal end of the camshaft, the clip including a detent defining the spring element and adapted to engage against the interior surface of the hinge and be seated in the groove defined in the interior surface of the hinge.

15. The assembly of claim 11 wherein the lever includes at least one hinge for coupling the lever to the distal end of the camshaft, the hinge including an exterior surface defining a groove, the assembly further comprising a clip coupled to the distal end of the camshaft, the clip including an arm defining the spring element and the arm engaging against the outer surface of the hinge and adapted to be seated in the groove in the exterior surface of the hinge.
